(19) United States
(12) Patent Application Publication
(10) Pub. No.: US 2021/0072601 A1
(43) Pub. Date: Mar. 11, 2021

(54) Aligning Method for Liquid Crystal Panel, Liquid Crystal Panel and Display Device

(71) Applicant: CHENGDU CEC PANDA DISPLAY TECHNOLOGY CO., LTD., Chengdu City, Sichuan (CN)

(72) Inventors: Makoto KAMBE, Chengdu City (CN); Guangsheng LI, Chengdu City (CN); MINGXIN DAI, Chengdu City (CN); Lin PENG, Chengdu City (CN); Fan LI, Chengdu City (CN); Bo ZHANG, Chengdu City (CN); Zenghui LI, Chengdu City (CN)

(73) Assignee: Chengdu CEC Panda Display Technology Co., Ltd., Chengdu City, Sichuan (CN)

(21) Appl. No.: 16/756,964

(22) PCT Filed: Mar. 23, 2020
(86) PCT No.: PCT/CN2020/080720

§ 371 Date: Nov. 24, 2020

(30) Foreign Application Priority Data
Jun. 10, 2019 (CN) 201910495762.6

(51) Int. Cl. G02F 1/1337; G02F 1/1343; G02F 1/1341; G02F 1/1333; G02F 1/1335; G02F 1/1368; G02F 1/1362; H01L 27/12

(52) U.S. Cl. CPC G02F 1/133788; G02F 1/13439; G02F 1/1341; G02F 1/133711; G02F 1/133345; G02F 1/133512; G02F 2001/136222; G02F 1/136286; G02F 1/134336; H01L 27/1259; G02F 2001/133742; G02F 2001/133746; G02F 2201/123; G02F 1/1368

(57) ABSTRACT

An aligning method for a liquid crystal panel, a liquid crystal panel and a display device are provided, The method includes: forming a first electrode and a first alignment film covering the first electrode on a first multilayer substrate, forming a second electrode and a second alignment film covering the second electrode on a second multilayer substrate arranged opposite to the first multilayer substrate, forming a liquid crystal layer between the first alignment film and the second alignment film, and irradiating the second multilayer substrate using ultraviolet light to align the second alignment film and the liquid crystal layer, that is, the second alignment film has a pre-tilt angle, and the first alignment film is a vertically aligned alignment film without need of alignment by partition.

### CROSS-REFERENCE TO RELATED APPLICATION

The present disclosure claims priority of the Chinese Patent Application with the filing number CN201910495762.6 filed on Jun. 10, 2019 with the Chinese Patent Office, and entitled “Aligning Method for Liquid Crystal Panel, Liquid Crystal Panel and Display Device”, the contents of which are incorporated herein by reference in their entirety.

### TECHNICAL FIELD

The present disclosure relates to the technical field of display device manufacture, in particular to an aligning method for a liquid crystal panel, a liquid crystal panel and a display device.

### BACKGROUND ART

Liquid crystal display (LCD) has many advantages such as thin body, power saving and no radiation, and is widely applied, for example, in LCD televisions, mobile phones, personal digital assistants, digital cameras, computer screens or laptop screens. At present, TFT-LCD liquid crystal panels may be classified into three major types, i.e., twisted nematic/super twisted nematic (TN/STN) type, in-plane switching (IPS) type and vertical alignment (VA) type. Ultraviolet induced multi-domain vertical alignment (UV²A) is a photo-alignment technology for the VA type liquid crystal panels, whose name comes from multiplication of ultraviolet UV and the VA mode of the liquid crystal panel, and the principle thereof is to use UV light to realize an accurate alignment control of liquid crystal molecules. The UV²A technology can realize the state that all liquid crystal molecules are tilted towards a designated direction using an alignment film, therefore, when an electric field is applied, the liquid crystal molecules may be tilted simultaneously towards the same direction, such that a response speed of a liquid crystal display is increased to 2 times of its original response speed, and as a pixel can still be divided into a plurality of regions without use of protrusions or slits, an aperture ratio of the pixel is significantly improved compared with the original practice where a plurality of regions are formed by using protrusions, and further the advantages such as reduced power consumption and cost saving are rendered.

In the conventional UV²A alignment, a substrate is partitioned into a plurality of regions, so as to partially change the alignment direction of the substrate, an aligning method usually used is a scanning exposure method, and a mask dedicated to alignment by partition is provided on the substrate. For example, in an aligning method for 4-domain pixel, firstly, taking an arrangement direction of different sub-pixel units as a row direction, a direction perpendicular to the row direction as a longitudinal direction, and a distance of one sub-pixel unit in the row direction as a period of UV²A irradiation at the TFT side, a sub-pixel unit in the TFT side longitudinal direction is divided into two portions, namely, a left portion and a right portion, wherein the left half portion of the TFT side pixel unit is irradiated to complete an exposure alignment of the left half portion at the TFT side, and then the right half portion of the TFT side pixel unit is irradiated to complete the exposure alignment of the right half portion, wherein the left half portion and the right half portion have opposite exposure directions, and the exposure directions of the ultraviolet light is parallel to a conveyance direction of the substrate; taking a distance of one sub-pixel unit in the longitudinal direction as the period of UV²A irradiation at the CF side, the sub-pixel unit in the CF side row direction is divided into two portions, namely, an upper portion and a lower portion, wherein the upper half portion of the CF side pixel unit is irradiated to complete the exposure alignment of the upper half portion at the CF side, and then the lower half portion of the CF side pixel unit is irradiated to complete the exposure alignment of the lower half portion, wherein the upper half portion and the lower half portion have opposite exposure directions, and the exposure directions of the ultraviolet light is parallel to the conveyance direction of the substrate.

However, the substrate at the TFT side and the substrate at the CF side require alignment treatments, which will increase the manufacturing processes, and raise the cost.

### SUMMARY

The present disclosure provides an aligning method for a liquid crystal panel, a liquid crystal panel and a display device, which can simplify the alignment procedures, and reduce the cost.

An embodiment of the present disclosure provides an aligning method for a liquid crystal panel, including steps of:

forming a first electrode and a first alignment film configured to cover the first electrode on a first multilayer substrate;

forming a second electrode and a second alignment film configured to cover the second electrode on a second multilayer substrate that is arranged opposite to the first multilayer substrate;

forming a liquid crystal layer between the first alignment film and the second alignment film; and

irradiating the second alignment film and the second multilayer substrate using ultraviolet light to align the liquid crystal layer.

Optionally, in the aligning method for a liquid crystal panel provided in the present disclosure, the first alignment film is a vertically aligned alignment film.

Optionally, in the aligning method for a liquid crystal panel provided in the present disclosure, the second multilayer substrate is irradiated using ultraviolet light, and to align the second alignment film and the liquid crystal layer includes: placing the second multilayer substrate on a supporting surface, placing a mask above the supporting surface, disposing the second multilayer substrate between the mask and the supporting surface, placing a light source capable of emitting ultraviolet light above the mask, and providing one or more slits on the mask, through which ultraviolet light emitted from the light source is able to pass to irradiate the second multilayer substrate.

Optionally, in the aligning method for a liquid crystal panel provided in the present disclosure, the second alignment film includes phototactic monomers, the liquid crystal layer includes liquid crystal molecules, and irradiating the second multilayer substrate with ultraviolet light includes:

irradiating the second multilayer substrate with ultraviolet light to enable the phototactic monomers and the liquid crystal molecules to be arranged at a pre-tilt angle.

Optionally, in the aligning method for a liquid crystal panel provided in the present disclosure, the pre-tilt angle is 80-90°

Optionally, in the aligning method for a liquid crystal panel provided in the present disclosure, a wavelength of the ultraviolet light is 100-400 nm, an exposure amount of the ultraviolet light is 10-1000 mJ/cm², and irradiation time of the ultraviolet light is 10-200 s.

Optionally, in the aligning method for a liquid crystal panel provided in the present disclosure, the second multilayer substrate includes a pixel electrode, wherein the liquid crystal panel has a pixel in which four orientation regions having liquid crystal molecules tilted at different angles are arranged in a long side direction of the pixel, and when a direction along a short side of the pixel is defined as 0°, the pixel includes: a first orientation region with an tilt angle of 135°; a second orientation region with an tilt angle of 225°; a third orientation region with an tilt angle of 315°; and a fourth orientation region with an tilt angle of 45°; and

when the liquid crystal panel is viewed from top, a twist angle of the liquid crystal molecules is 0° in each of the four orientation regions.

Optionally, in the aligning method for a liquid crystal panel provided in the present disclosure, the pixel electrode includes a first pixel electrode and a second pixel electrode, wherein the first pixel electrode is configured to apply a voltage to the first orientation region and the second orientation region, and the second pixel electrode is configured to apply a voltage to the third orientation region and the fourth orientation region.

Optionally, in the aligning method for a liquid crystal panel provided in the present disclosure, the pixel electrode includes a first pixel electrode and a second pixel electrode, and the first pixel electrode and the second pixel electrode apply different voltages to the liquid crystal layer respectively.

Optionally, in the aligning method for a liquid crystal panel provided in the present disclosure, the first multilayer substrate is a color filter substrate, and the second substrate is an array substrate.

Optionally, in the aligning method for a liquid crystal panel provided in the present disclosure, the first multilayer substrate includes a first substrate, wherein the first electrode is configured to cover the first substrate, and the first electrode is located between the first substrate and the first alignment film.

Optionally, in the aligning method for a liquid crystal panel provided in the present disclosure, the second multilayer substrate includes a second substrate, and an electrode line, an insulation layer, one or more black matrices and a color-resist layer which are provided in order on the second substrate, wherein the second electrode is configured to cover the color-resist layer, and the second electrode is located between the color-resist layer and the second alignment film.

Optionally, in the aligning method for a liquid crystal panel provided in the present disclosure, the first substrate and the second substrate are made of glass, the first electrode and the second electrode are transparent electrodes, and materials for forming the first alignment film and the second alignment film include polyimide.

Optionally, in the aligning method for a liquid crystal panel provided in the present disclosure, the electrode line includes a plurality of scan lines and a plurality of data lines, wherein the plurality of scan lines and the plurality of data lines perpendicularly cross each other to divide the second substrate into a plurality of pixel regions.

Optionally, in the aligning method for a liquid crystal panel provided in the present disclosure, the data lines are provided in the same layer as the color-resist layer, the color-resist layer includes a plurality of color resistors, each of the pixel regions is corresponding to one color resist, and each of the pixel regions has one of the pixel electrodes.

Optionally, in the aligning method for a liquid crystal panel provided in the present disclosure, in each of the pixel regions, one thin film transistor is provided at each intersection between the corresponding scan line and data line, and the thin film transistor uses the scan line as a gate, a semiconductor layer as a channel, and the data line as a source to form a thin film transistor switching device.

Optionally, in the aligning method for a liquid crystal panel provided in the present disclosure, a plurality of pixel electrodes are provided, and the plurality of pixel electrodes are provided on the second substrate in a form of rectangular array.

Optionally, in the aligning method for a liquid crystal panel provided in the present disclosure, each of the pixel electrodes is provided inside one of the pixel regions. An embodiment of the present disclosure further provides a liquid crystal panel, which is aligned by using the above aligning method for a liquid crystal panel.

An embodiment of the present disclosure further provides a display device, including the above liquid crystal panel.

The present disclosure provides the aligning method for a liquid crystal panel, the liquid crystal panel and the display device. In the aligning method for a liquid crystal panel, the first electrode and the first alignment film configured to cover the first electrode are formed on the first multilayer substrate, the second electrode and the second alignment film configured to cover the second electrode are formed on the second multilayer substrate that is arranged opposite to the first multilayer substrate, the liquid crystal layer is formed between the first alignment film and the second alignment film, the second alignment film and the second multilayer substrate are irradiated using ultraviolet light to align the liquid crystal layer, that is, the second alignment film has a pre-tilt angle, and the first alignment film is a vertically aligned alignment film and thus does not need to be subjected to the alignment by partition. The aligning method for a liquid crystal panel provided in the embodiments of the present disclosure does not require the alignment by partition, while only the second multilayer substrate is provided with the mask for performing alignment, and the first multilayer substrate is not provided with a mask and requires no alignment, thereby the aligning process of the liquid crystal panel is simplified, and the cost is reduced.

### BRIEF DESCRIPTION OF DRAWINGS

In order to more clearly illustrate technical solutions in the embodiments of the present disclosure or the prior art, accompanying drawings needed to be used for description of the embodiments or the prior art will be introduced briefly below, and apparently, the accompanying drawings in the description below merely show some embodiments of the present disclosure, and those ordinarily skilled in the art still could obtain other accompanying drawings in light of these accompanying drawings, without inventive effort.

FIG. 1 is a flowchart of an aligning method for a liquid crystal panel provided in an embodiment of the present disclosure;

FIG. 2 is a schematic plan view showing a relation between a pixel electrode and orientation regions in one pixel according to an aligning method for a liquid crystal panel provided in an embodiment of the present disclosure; and

FIG. 3 is an overall structural schematic view of a liquid crystal panel provided in an embodiment of the present disclosure.

### DESCRIPTION OF REFERENCE SIGNS

10—pixel;
20—first multilayer substrate;
201—first substrate;
202—first electrode;
203—first alignment film;
30—second multilayer substrate;
301—second substrate;
302—electrode line;
303—insulation layer;
304—black matrix;
305—color-resist layer;
306—second electrode;
307—second alignment film;
308—pixel electrode;
3081—first pixel electrode;
3082—second pixel electrode;
40—liquid crystal layer.

### DETAILED DESCRIPTION OF EMBODIMENTS

The technical solutions in the embodiments of the present disclosure will be described clearly and completely below in conjunction with the embodiments of the present disclosure, and apparently, some but not all embodiments of the present disclosure are described. All other embodiments obtained by those ordinarily skilled in the art based on the embodiments of the present disclosure without any inventive effort shall fall within the scope of protection of the present disclosure.

In the description of the present disclosure, it should be understood that orientational or positional relations indicated by terms such as “between” are based on orientational or positional relations as shown in the accompanying drawings, merely for facilitating the description of the present disclosure and simplifying the description, rather than indicating or implying that related devices or elements have to be in the specific orientation or configured and operated in a specific orientation, therefore, they should not be construed as limitation on the present disclosure.

In the present disclosure, unless otherwise specified and defined explicitly, a first feature being “above” or “below” a second feature may include the first feature and the second feature being in direct contact, or the first feature and the second feature being in contact through an intermediary. Moreover, the first feature being “on”, “above” or “over” the second feature may be that the first feature is right above or not right above the second feature, or merely means that the level of the first feature is higher than that of the second feature. The first feature being “under”, “below” or “beneath” the second feature may be that the first feature is directly below or not directly below the second feature, or merely means the level of the first feature being lower than that of the second feature.

Besides, terms “first” and “second” are merely for descriptive purpose, but should not be construed as indicating or implying relative importance or suggesting the number of a related technical feature. Thus, a feature defined with “first” or “second” may explicitly or implicitly mean that one or more such features are included.

With the development of display technology, flat panel display devices such as liquid crystal display (LCD), due to advantages such as high image quality, power saving, thin body and wide application range, are widely applied in various consumer electronic products such as mobile phones, televisions, personal digital assistants, digital cameras, laptops and desktop computers. The liquid crystal display devices currently on the market mostly have a color filter substrate of backlight type, which includes a liquid crystal panel and a backlight module. A liquid crystal panel usually includes a color filter (CF) substrate, a thin film transistor (TFT) substrate (also called as array substrate) and liquid crystal (LC) sandwiched between the color filter substrate and the array substrate. The operating principle of the liquid crystal panel is that liquid crystal molecules are disposed between a color filter substrate and an array substrate which are parallel to each other, many vertical and horizontal data lines and scan lines are arranged between the two substrates, and the liquid crystal molecules are controlled to change or not to change their directions by powering on or off the data lines and the scan lines, so that light of the backlight module is refracted out to generate an image.

At present, TFT-LCD liquid crystal panels may be classified into three major types, i.e., twisted nematicisuper twisted nematic (TN/STN) type, in-plane switching (IPS) type and vertical alignment (VA) type. Ultraviolet induced multi-domain vertical alignment (UV²A) is a photo-alignment technology for VA type liquid crystal panels, named from multiplication of ultraviolet UV and the VA mode of the liquid crystal panel, and the principle thereof is to use UV light to realize an accurate alignment control of liquid crystal molecules. The UV²A technology can realize the state that all liquid crystal molecules are tilted towards a designated direction using an alignment film, therefore, when an electric field is applied, the liquid crystal molecules can be tilted simultaneously towards the same direction, such that a response speed of a liquid crystal display is increased to 2 times of its original response speed, and as a pixel can still be divided into a plurality of regions without use of protrusions or slits, an aperture ratio of the pixel is significantly improved compared with the original practice where a plurality of regions are formed by using protrusions, and further the advantages such as reduced power consumption and cost saving are rendered.

With the development of large display panels, the level of a good visual performance becomes higher and higher, and UV²A is a display technology with many advantages, such as a simple process, a wider viewing angle and a faster response speed, which can better reduce the cost if in cooperation with the Color on Array (“COA” for short) technology.

In the conventional UV²A alignment, a substrate is partitioned into a plurality of regions, so as to partially change the alignment direction of the substrate, an aligning method usually used is a scanning exposure method, and a mask dedicated to alignment by partition is provided on the substrate. For example, in an aligning method for 4-domain pixel, firstly, taking an arrangement direction of different sub-pixel units as a row direction, a direction perpendicular to the row direction as a longitudinal direction, and a distance of one sub-pixel unit in the row direction as a period of UV²A irradiation at the TFT side, a sub-pixel unit in the TFT side longitudinal direction is divided into two portions, namely, a left portion and a right portion, wherein the left half portion of the TFT side pixel unit is irradiated to complete exposure alignment of the left half portion at the TFT side, and then the right half portion of the TFT side pixel unit is irradiated to complete the exposure alignment of the right half portion, wherein the left half portion and the right half portion have opposite exposure directions, and the exposure directions of the ultraviolet light is parallel to a conveyance direction of the substrate; taking a distance of one sub-pixel unit in the longitudinal direction as the period of UV²A irradiation at the CF side, the sub-pixel unit in the CF side row direction is divided into two portions, namely, an upper portion and a lower portion, wherein the upper half portion of the CF side pixel unit is irradiated to complete the exposure alignment of the upper half portion at the CF side, and then the lower half portion of the CF side pixel unit is irradiated to complete the exposure alignment of the lower half portion, wherein the upper half portion and the lower half portion have opposite exposure directions, and the exposure directions of the ultraviolet light is parallel to the conveyance direction of the substrate. However, the substrate at the TFT side and the substrate at the CF side require alignment treatments, which will increase the manufacturing process, and raise the cost,

In order to solve the above problems, the present disclosure provides an aligning method for a liquid crystal panel, in which a first electrode and a first alignment film covering the first electrode are formed on a first multilayer substrate, a second electrode and a second alignment film covering the second electrode are formed on a second multilayer substrate arranged opposite to the first multilayer substrate, a liquid crystal layer is formed between the first alignment film and the second alignment film, the second multilayer substrate is irradiated with ultraviolet light for alignment of the liquid crystal layer, that is, the second alignment film has a pre-tilt angle, wherein the first alignment film is a vertically aligned alignment film and thus does not need to be subjected to the alignment by partition. The aligning method for a liquid crystal panel provided in the embodiment of the present disclosure does not require the alignment by partition, while only the second multilayer substrate is provided with a mask for performing alignment, and the first multilayer substrate is not provided with a mask and requires no alignment, thereby the aligning process of the liquid crystal panel is simplified, and the cost is reduced.

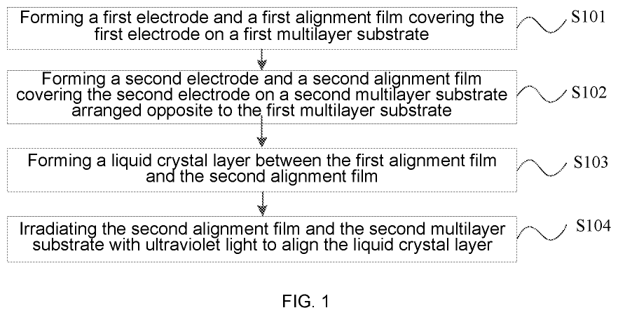

FIG. 1 is a flowchart of an aligning method for a liquid crystal panel provided in an embodiment of the present disclosure. Referring to FIG. 1, an aligning method for a liquid crystal panel provided in an embodiment of the present disclosure may include following steps;

S101, forming a first electrode 202 and a first alignment film 203 configured to cover the first electrode 202 on a first multilayer substrate 20.

Specifically, the first multilayer substrate 20 may be a color filter substrate. The first electrode 202 may be arranged on the first multilayer substrate 20, and the first electrode 202 may be a transparent electrode, A polyimide solution may be coated on the first electrode 202, and the polyimide solution gives a flat film with a uniform thickness with the help of its own surface tension, and the first alignment film 203 is then obtained after high temperature condensation, that is, materials for forming the first alignment film 203 include polyimide.

S102, forming a second electrode 306 and a second alignment film 307 configured to cover the second electrode 306 on a second multilayer substrate 30 arranged opposite to the first multilayer substrate 20.

Specifically, the second multilayer substrate 30 may be an array substrate. The second electrode 306 may be provided on the second multilayer substrate 30, and the second electrode 306 may be a transparent electrode. A polyimide solution may be coated on the second electrode 306, the polyimide solution gives a flat film with a uniform thickness with the help of its own surface tension, and the second alignment film 307 is then obtained after high temperature condensation, that is, materials for forming the second alignment film 307 include polyimide.

It should be noted that S101 and S102 are only descriptions for different operation steps, without preference in order, and it is also feasible that S102 is performed first, before S101 is performed.

S103, forming a liquid crystal layer 40 between the first alignment film 203 and the second alignment film 307.

Specifically, liquid crystal molecules containing phototactic monomers may be injected between the first alignment film 203 and the second alignment film 307 so as to form this liquid crystal layer 40, i.e., the liquid crystal layer 40 includes the phototactic monomers and the liquid crystal molecules.

S104, irradiating the second multilayer substrate 30 using ultraviolet light for aligning the liquid crystal layer 40.

Specifically, ultraviolet light is emitted by a light source, and the ultraviolet light passes through a mask to irradiate the second multilayer substrate 30 to align the second alignment film 307 and the liquid crystal layer 40, such that the phototropic monomers undergo a polymerization reaction to be deposited on a surface of the second alignment film 307, and the liquid crystal molecules are fixed at a pre-tilt angle. That is, the second alignment film 307 has a pre-tilt angle, and the first alignment film 203 is a vertically aligned alignment film and thus does not need to be subjected to the alignment by partition.

In the aligning method for a liquid crystal panel provided in the embodiments of the present disclosure, the first electrode and the first alignment film configured to cover the first electrode are formed on the first multilayer substrate, the second electrode and the second alignment film configured to cover the second electrode are formed on the second multilayer substrate arranged opposite to the first multilayer substrate, the liquid crystal layer is formed between the first alignment film and the second alignment film, the second multilayer substrate is provided with the mask, and the second multilayer substrate is irradiated with ultraviolet light to align the second alignment film and the liquid crystal layer, that is, the second alignment film has a pre-tilt angle, and the first alignment film is a vertically aligned alignment film and thus does not need to be subjected to the alignment by partition. The aligning method for a liquid crystal panel provided in the embodiments of the present disclosure, the first multilayer substrate does not need to be subjected to the alignment by partition, while only the second multilayer substrate is configured with the mask for performing alignment, and the first multilayer substrate is not provided with a mask and requires no alignment, thereby the aligning process of the liquid crystal panel is simplified, and the cost is reduced.

In specific implementation, in the aligning method for a liquid crystal panel provided in an embodiment of the present disclosure, the second alignment film 307 may include phototactic monomers, the liquid crystal layer 40 may include liquid crystal molecules, and irradiating the second multilayer substrate 30 using ultraviolet light may include:

irradiating the second multilayer substrate 30 using ultraviolet light to enable the phototactic monomers and the liquid crystal molecules to be arranged at a pre-tilt angle.

Specifically, the second multilayer substrate 30 may be placed on a supporting surface, and the mask may be placed above the supporting surface, such that the second multilayer substrate 30 is disposed between the mask and the supporting surface. A light source that can emit ultraviolet light may be placed above the mask. The mask may have one or more slits, through which ultraviolet light emitted from the light source can pass to irradiate the second multilayer substrate 30, enabling the phototactic monomers and the liquid crystal molecules to be arranged at a pre-tilt angle.

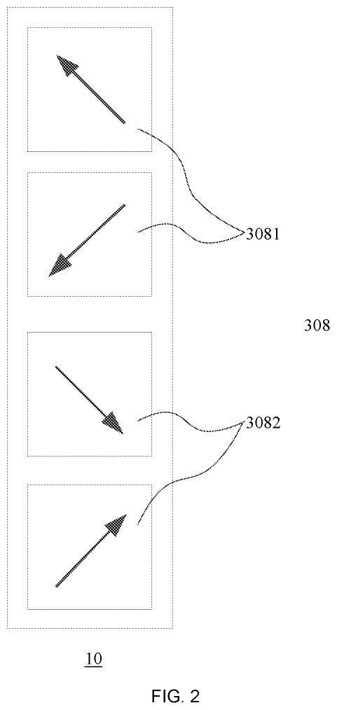

FIG. 2 is a schematic plan view showing a relation between a pixel electrode and orientation regions in one pixel according to an aligning method for a liquid crystal panel provided in an embodiment of the present disclosure. Referring to FIG. 2, the second multilayer substrate 30 may include a pixel electrode 308, the liquid crystal panel may have a pixel 10 in which four orientation regions having liquid crystal molecules tilted at different angles, and the four orientation regions are arranged in a long side direction of the pixel 10, and when a direction along a short side of the pixel 10 is defined as 0°, the pixel 10 may include: a first orientation region with an tilt angle of 135°; a second orientation region with an tilt angle of 225°; a third orientation region with an tilt angle of 315°; and a fourth orientation region with an tilt angle of 45°, wherein there is a difference of 90° between the tilt angles of adjacent orientation regions, thus good viewing angle characteristics can be rendered.

When the liquid crystal panel is viewed from top, a twist angle of he liquid crystal molecules is 0° in each of the four orientation regions.

The pixel electrode 308 may include: a first pixel electrode 3081 and a second pixel electrode 3082, wherein the first pixel electrode 3081 is configured to apply a voltage to the first orientation region and the second orientation region from top to bottom among the four orientation regions described above in FIG. 2; the second pixel electrode 3082 is configured to apply a voltage to the third orientation region and the fourth orientation region from top to bottom among the four orientation regions described above in FIG. 2, and the first pixel electrode 3081 and the second pixel electrode 3082 further may apply different voltages to the liquid crystal layer 40 respectively.

Optionally, in the aligning method for a liquid crystal panel provided in an embodiment of the present disclosure, the pre-tilt angle may be 80-90°, such that the liquid crystal molecules have a quick response, a good uniformity of deflection, and a good consistency of deflection. Specifically, the pre-tilt angle is an included angle between a long axis direction of the liquid crystal molecules and the second multilayer substrate 30 or the first multilayer substrate 20.

Optionally, the pre-tilt angle of the liquid crystal molecules is 80.1-82.7°, or 83.5-84.7°, or 87.1°-88.1°, or 88.22-90°, wherein the liquid crystal molecules have the best uniformity of deflection and the best consistency of deflection when the pre-tilt angle is 84.5°, and the liquid crystal molecules have the quickest response when the pre-tilt angle is 89.8°.

In specific implementation, in the aligning method for a liquid crystal panel provided in an embodiment of the present disclosure, the wavelength of the ultraviolet light is 100-400 nm, the exposure amount of the ultraviolet light (which may also be referred to as irradiance (or illuminance of radiation) of the ultraviolet light) is 10-1000 mJ/cm², and the irradiation time of the ultraviolet light is 10-200 s.

Further, in the aligning method for a liquid crystal panel provided in an embodiment of the present application, the first multilayer substrate 20 may be a color filter substrate, and the second multilayer substrate 30 may be an array substrate.

Specifically, in the aligning method for a liquid crystal panel provided in an embodiment of the present disclosure, the first multilayer substrate 20 may include a first substrate 201, the first electrode 202 may partially cover the first substrate 201, the first electrode 202 may be located between the first substrate 201 and the first alignment film 203, and the first alignment film 203 may partially cover the first electrode 202.

In specific implementation, the first substrate 201 may be made of glass, and the first electrode 202 may be a transparent electrode, wherein the transparent conductive film (“TCF” for short), also called as transparent electrode currently is mainly applied to ITO thin films, AZO (Aluminum-doped Zinc Oxide) and so on. An ITO (which is an abbreviation of indium tin oxide) thin film, is a transparent semiconductor thin film. The ITO thin film has good transparency and good conductivity. Preparation methods of the ITO thin film include evaporation, sputtering, reactive ion plating, chemical vapor deposition, pyrolytic spraying and so on, and the ITO thin film has good chemical stability, good thermal stability and good pattern processing characteristics. The first alignment film 203 may be a vertically aligned alignment film, the liquid crystal molecules close to the first alignment film 203 are perpendicular to the first alignment film 203, and materials for forming the first alignment film 203 may include polyimide.

Specifically, in the aligning method for a liquid crystal panel provided in an embodiment of the present disclosure, the second multilayer substrate 30 may include a second substrate 301, and an electrode line 302, an insulation layer 303, one or more black matrices 304 and a color-resist layer 305 which are provided in order on the second substrate 301, wherein the insulation layer 303 may partially cover the second substrate 301, the color-resist layer 305 may partially cover the insulation layer 303, the one or more black matrices 304 may be embedded in the color-resist layer 305 and in contact with a surface of the insulation layer 303, the electrode line 302 may be embedded in the insulation layer 303 and in contact with a surface of the second substrate 301, the second electrode 306 covers the color-resist layer 305, and the second electrode 306 is located between the color-resist layer 305 and the second alignment film 307, that is, the second alignment film 307 is provided on a side of the second electrode 306 facing away from the color-resist layer 305.

In the above, the second substrate 301 may be made of glass, the second electrode 306 may be a transparent electrode, the second alignment film 307 may have a pre-tilt angle, and materials for forming the second alignment film 307 may include polyimide.

In the UV²A display mode, a region with non-uniform liquid crystal alignment is referred to as a dark fringe region, which region is not uniformly aligned. The dark fringe is mainly caused by the influence from the transparent electrodes between adjacent pixels. In order to solve the above problem, in the aligning method for a liquid crystal panel provided in the present disclosure, twist alignment is changed to parallel alignment, the first multilayer substrate 20 is not aligned, the first alignment film 203 is a vertically aligned alignment film, liquid crystal molecules close to the first alignment film 203 are perpendicular to the first alignment film 203, the second multilayer substrate 30 is aligned, and the second alignment film 307 has a pre-tilt angle so as to reduce the dark fringe region, so that the area region where generation of the dark fringe may occur in the liquid crystal panel is reduced, and transmittance of the liquid crystal panel can be improved.

In order to realize better color display of the liquid crystal panel, a color filter (film) may be additionally provided on the array substrate, so that three primary colors RGB are realized on the array substrate, which avoids the alignment operation on the array substrate and the color filter substrate, such that the liquid crystal panel can better perform full-color display without affecting its transmittance. The above technology is called as COA (color on array) technology. In the aligning method for a liquid crystal panel provided in an embodiment of the present application, the first multilayer substrate 20 may be a color filter substrate, and the second multilayer substrate 30 may be an array substrate. The first multilayer substrate 20 may include a first substrate 201, the first electrode 202 may partially cover the first substrate 201, the first electrode 202 may be located between the first substrate 201 and the first alignment film 203, and the first alignment film 203 may partially cover the first electrode 202. The second multilayer substrate 30 may include a second substrate 301, and an electrode line 302, an insulation layer 303, one or more black matrices 304 and a color-resist layer 305 which are provided in order on the second substrate 301. In the COA mode, the first multilayer substrate 20 does not need the alignment by partition, and then it is unnecessary to track the alignment or configure a BM matrix for the alignment by partition, etc.

Specifically, the color-resist layer 305 may include a red color resist, a green color resist and a blue color resist. In the present embodiment, by providing the color-resist layer 305 to include color-resists of three colors, namely, the red color resist, the green color resist and the blue color resist (red, green and blue are three primary colors), and by filtering light deflected by the liquid crystal molecules using the red color resist, the green color resist and the blue color resist, various colors desired can be synthesized, and the color display effect of the liquid crystal display device is improved.

Specifically, the electrode line 302 may include a plurality of scan lines and a plurality of data lines, and the plurality of scan lines and the plurality of data lines perpendicularly cross each other to divide the second substrate 30 into a plurality of pixel regions. The data lines may be provided in the same layer as the color-resist layer 305, each pixel region is corresponding to one color resist, and there is one pixel electrode 308 in each pixel region. In each pixel region, one thin film transistor is provided at each intersection between the corresponding scan line and data line, and the thin film transistor uses the scan line as a gate, a semiconductor layer as a channel, and the data line as a source to form a thin film transistor switching device. In the above, a plurality of pixel electrodes 308 may be provided, and the plurality of pixel electrodes 308 are provided on the second substrate 30 in a form of rectangular array. Each pixel electrode 308 is provided inside one pixel region, so as to control deflection of liquid crystal molecules within a liquid crystal layer corresponding to this pixel region, further realizing display of an image.

Optionally, in the aligning method for a liquid crystal panel provided in an embodiment of the present disclosure, the first alignment film and the second alignment film may be made of polyimide.

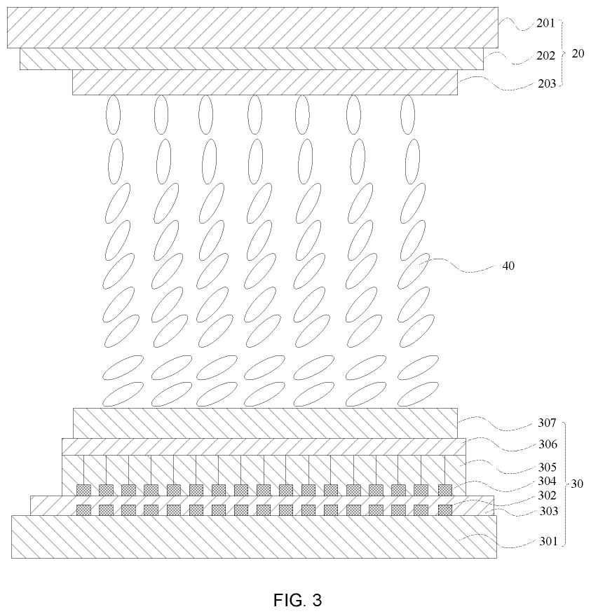

FIG. 3 is an overall structural schematic view of a liquid crystal panel provided in an embodiment of the present disclosure. Referring to FIG. 3, an embodiment of the present disclosure provides a liquid crystal panel, which is aligned using the aligning method for a liquid crystal panel provided in the above embodiments.

In some embodiments, the liquid crystal panel may include a first multilayer substrate 20, a second multilayer substrate 30, and a liquid crystal layer 40 located between the first multilayer substrate 20 and the second multilayer substrate 30.

Optionally, the first multilayer substrate 20 may include a first substrate 201, wherein the first electrode 202 is configured to cover the first substrate 201, and the first electrode 202 is located between the first substrate 201 and the first alignment film 203.

Optionally, the second multilayer substrate 30 may include a second substrate 301, and an electrode line 302, an insulation layer 303, one or more black matrices 304 and a color-resist layer 305 which are provided in order on the second substrate 301, wherein the second electrode 306 is configured to cover the color-resist layer 305, and the second electrode 306 is located between the color-resist layer 305 and the second alignment film 307.

The liquid crystal layer 40 is located between the first alignment film 203 and the second alignment film 307.

The liquid crystal panel provided in the embodiments of the present disclosure is aligned by the aligning method for a liquid crystal panel, wherein the first electrode and the first alignment film configured to cover the first electrode are formed on the first multilayer substrate, the second electrode and the second alignment film configured to cover the second electrode are formed on the second multilayer substrate arranged opposite to the first multilayer substrate, the liquid crystal layer is formed between the first alignment film and the second alignment film, the mask is provided, and the second multilayer substrate is irradiated using ultraviolet light to align the second alignment film and the liquid crystal layer, that is, the second alignment film has a pre-tilt angle, and the first alignment film is a vertically aligned alignment film and thus does not need the alignment by partition. The aligning method for a liquid crystal panel provided in the embodiment of the present disclosure does not require the alignment by partition, while only the second multilayer substrate is provided with the mask for performing alignment, and the first multilayer substrate is not provided with a mask and requires no alignment, thereby the aligning process of the liquid crystal panel is simplified, and the cost is reduced.

An embodiment of the present disclosure further provides a display device, including the liquid crystal panel provided in the above embodiments.

In the above, the structure of the liquid crystal panel has been described in detail in the above embodiments, and is not repeated redundantly herein in the present embodiment.

The display device provided in the embodiment of the present disclosure may be any product or component having a display function, such as electronic paper, mobile phone, tablet computer, television, laptop, digital photo frame and navigation device, which are not limited in the present embodiment.

The display device provided in the embodiment of the present disclosure includes the liquid crystal panel aligned by the aligning method for a liquid crystal panel, wherein the first electrode and the first alignment film configured to cover the first electrode are formed on the first multilayer substrate, the second electrode and the second alignment film configured to cover the second electrode are formed on the second multilayer substrate arranged opposite to the first multilayer substrate, the liquid crystal layer is formed between the first alignment film and the second alignment film, the mask is provided, and the second multilayer substrate is irradiated using ultraviolet light to align the second alignment film and the liquid crystal layer, that is, the second alignment film has a pre-tilt angle, and the first alignment film is a vertically aligned alignment film and thus does not need to be subjected to the alignment by partition. The aligning method for a liquid crystal panel provided in the embodiment of the present disclosure does not need the alignment by partition, while only the second multilayer substrate is provided with the mask for performing alignment, and the first multilayer substrate is not provided with a mask and requires no alignment, thereby the aligning process of the liquid crystal panel is simplified, and the cost is reduced.

It should be understood that in the description of the specification of the present disclosure, description with terms such as “some embodiments” and “one embodiment” means that a specific feature, structure, material or characteristic described in combination with this embodiment or example is contained in at least one embodiment or example of the present disclosure. In the present description, exemplary expressions of the above terms do not necessarily refer to the same embodiment or example. Moreover, the specific feature, structure, material or characteristic described can be combined in a appropriate manner in any one or more embodiments or examples. Besides, a person skilled in the art could integrate and combine different embodiments or examples described in the present description.

Furthermore, elements, structures or features described in one accompanying drawing or one embodiment of the present disclosure can be combined with elements, structures or features shown in one or more other accompanying drawings or one or more other embodiments in any appropriate manner.

Finally, it should be explained that the embodiments above are merely used for illustrating the technical solutions of the present disclosure, rather than limiting the present disclosure; while the detailed description is made to the present disclosure with reference to the preceding embodiments, those ordinarily skilled in the art should understand that they still could modify the technical solutions recited in the preceding embodiments, or make equivalent substitutions to some or all of the technical features therein; these modifications or substitutions do not make the corresponding technical solutions essentially depart from the scope of the technical solutions of the embodiments of the present disclosure.

### INDUSTRIAL APPLICABILITY

In summary, the present disclosure provides an aligning method for a liquid crystal panel, a liquid crystal panel and a display device, in which the alignment by partition is not needed, while only the second multilayer substrate is provided with a mask for performing alignment, and the first multilayer substrate is not provided with a mask and requires no alignment, thereby the aligning process of the liquid crystal panel is simplified and the cost is reduced.

1. An aligning method for a liquid crystal panel, comprising steps of:
forming, on a first multilayer substrate, a first electrode and a first alignment film configured to cover the first electrode;
forming, on a second multilayer substrate that is arranged opposite to the first multilayer substrate, a second electrode and a second alignment film configured to cover the second electrode;
forming a liquid crystal layer between the first alignment film and the second alignment film; and
irradiating the second multilayer substrate using ultraviolet light to align the second alignment film and the liquid crystal layer.

2. The aligning method for a liquid crystal panel according to claim 1, wherein the first alignment film is a vertically aligned alignment film.

3. The aligning method for a liquid crystal panel according to claim 1, wherein the second multilayer substrate is irradiated using ultraviolet light, and aligning the second alignment film and the liquid crystal layer comprises: placing the second multilayer substrate on a supporting surface, placing a mask above the supporting surface, disposing the second multilayer substrate between the mask and the supporting surface, placing a light source capable of emitting ultraviolet light above the mask, and providing one or more slits on the mask, through which ultraviolet light emitted from the light source is able to pass to irradiate the second multilayer substrate.

4. The aligning method for a liquid crystal panel according to claim 1, wherein the second alignment film comprises phototactic monomers, the liquid crystal layer comprises liquid crystal molecules, and irradiating the second multilayer substrate using ultraviolet light comprises:
irradiating the second multilayer substrate using ultraviolet light to enable the phototactic monomers and the liquid crystal molecules to be arranged at a pre-tilt angle.

5. The aligning method for a liquid crystal panel according to claim 4, wherein the pre-tilt angle is 80-90°

6. The aligning method for a liquid crystal panel according to claim 1, wherein a wavelength of the ultraviolet light is 100-400 nm, an exposure amount of the ultraviolet light is 10-1000 mJ/cm2, and irradiation time of the ultraviolet light is 10-200 s.

7. The aligning method for a liquid crystal panel according to claim 4, wherein
the second multilayer substrate comprises a pixel electrode, the liquid crystal panel has a pixel in which four orientation regions having liquid crystal molecules tilted at different angles are arranged in a long side direction of the pixel, and when a direction along a short side of the pixel is defined as 0°, the pixel comprises: a first orientation region with an tilt angle of 135°; a second orientation region with an tilt angle of 225°; a third orientation region with an tilt angle of 315°; and a fourth orientation region with an tilt angle of 45°; and
when the liquid crystal panel is viewed from top, a twist angle of the liquid crystal molecules is 0° in each of the four orientation regions.

8. The aligning method for a liquid crystal panel according to claim 7, wherein the pixel electrode comprises a first pixel electrode and a second pixel electrode, the first pixel electrode is configured to apply a voltage to the first orientation region and the second orientation region, and the second pixel electrode is configured to apply a voltage to the third orientation region and the fourth orientation region

9. The aligning method for a liquid crystal panel according to claim 7, wherein the pixel electrode comprises a first pixel electrode and a second pixel electrode, and the first pixel electrode and the second pixel electrode apply different voltages to the liquid crystal layer respectively.

10. The aligning method for a liquid crystal panel according to claim 1, wherein the first multilayer substrate is a color filter substrate, and the second multilayer substrate is an array substrate.

11. The aligning method for a liquid crystal panel according to claim 7, wherein the first multilayer substrate comprises a first substrate, the first electrode is configured to cover the first substrate, and the first electrode is located between the first substrate and the first alignment film.

12. The aligning method for a liquid crystal panel according to claim 11, wherein the second multilayer substrate comprises a second substrate, and an electrode line, an insulation layer, a black matrix and a color-resist layer which are provided on the second substrate in order, the second electrode is configured to cover the color-resist layer, and the second electrode is located between the color-resist layer and the second alignment film.

13. The aligning method for a liquid crystal panel according to claim 12, wherein the first substrate and the second substrate are made of glass, the first electrode and the second electrode are transparent electrodes, and materials for forming the first alignment film and the second alignment film comprise polyimide.

14. The aligning method for a liquid crystal panel according to claim 12, wherein the electrode line comprises a plurality of scan lines and a plurality of data lines, and the plurality of scan lines and the plurality of data lines perpendicularly cross each other to divide the second substrate into a plurality of pixel regions.

15. The aligning method for a liquid crystal panel according to claim 14, wherein the plurality of data lines are provided in the same layer as the color-resist layer, the color-resist layer comprises a plurality of color resistors, each of the pixel regions is corresponding to one respective color resist, and each of the pixel regions has one of the pixel electrodes.

16. The aligning method for a liquid crystal panel according to claim 14, wherein in each of the pixel regions, one thin film transistor is provided at each intersection between the respective scan line and the respective data line, and the thin film transistor uses the scan line as a gate, a semiconductor layer as a channel, and the data line as a source to form a thin film transistor switching device.

17. The aligning method for a liquid crystal panel according to claim 12, wherein a plurality of pixel electrodes are provided, and the plurality of pixel electrodes are provided on the second substrate in a form of rectangular array.

18. The aligning method for a liquid crystal panel according to claim 17, wherein each of the pixel electrodes is provided inside one of the pixel regions.

19. A liquid crystal panel, aligned by using the aligning method for a liquid crystal panel according to claim 1.

20. A display device, comprising the liquid crystal panel according to claim 19.
